(19) United States
(12) Patent Application Publication
(10) Pub. No.: US 2025/0301826 A1
(43) Pub. Date: Sep. 25, 2025

(54) NANOWIRE BASED LIGHT EMITTING DEVICES

(71) Applicant: NS Nanotech, Inc., Ann Arbor, MI (US)

(72) Inventors: Werner GOETZ, Palo Alto, CA (US); David LALEYAN, Pierrefonds (CA); Seth COE-SULLIVAN, Rolling Hills Estates, CA (US)

(21) Appl. No.: 19/229,841

(22) Filed: Jun. 5, 2025

Related U.S. Application Data
(63) Continuation of application No. PCT/US2023/082788, filed on Dec. 6, 2023.
(60) Provisional application No. 63/430,613, filed on Dec. 6, 2022.

(51) Int. Cl. H10H 20/812; H10H 20/01; H10H 20/813; H10H 20/825

(52) U.S. Cl. CPC H10H 20/812; H10H 20/01335; H10H 20/016; H10H 20/8132; H10H 20/8252

(57) ABSTRACT

Devices and methods of manufacturing light emitting devices including selective area epitaxy deposited N-polar semiconductors. The devices and methods can be utilized to realize high-quality, high-performance and/or high-efficiency nanowire based light emitting devices.

### CROSS-REFERENCE TO RELATED APPLICATIONS

This application is a continuation of Patent Cooperation Treaty Application No. PCT/US2023/082788 filed Dec. 6, 2023, which claims priority to U.S. Provisional Patent Application No. 63/430,613 filed Dec. 6, 2022, both of which are incorporated herein in their entirety.

### BACKGROUND OF THE INVENTION

This section provides background information related to the present technology which is not necessarily prior art.

Significant efforts have been put into the development of efficient micro and nano light emitting devices for future display technologies, due to their marked benefits over existing displays. The display industry requires improved display technologies that continue to deliver higher quality images. Common image quality parameters are resolution, brightness, efficiency, speed, color gamut and dynamic range. Due to their very high efficiency potential, micro and nano light emitting device based displays offer great promise to achieve great performance in many of these critical display parameters. However, to date, there is a fundamental trade-off between resolution (pixel size) and efficiency. Thus, for high resolution micro-displays, or cost effective large displays, as the LED size is decreased, the efficiency becomes so low that better overall performance can be achieved with other display technologies, such as LCD or OLED.

Nanowire-based light emitting devices have the promise to break this tradeoff. Since each nanowire can operate as a complete LED, 1 millimeter (mm) or less in diameter. The efficiency of light emitting nanowires can remain constant so long as one or many nanowires are wired in parallel to make a single light emitting device or pixel. Thus, nanowire light emitting devices, with lateral diameters from 1 mm to 100 nm or less, can exhibit constant efficiency. In addition, the efficiency of such nanowire light emitting devices can be made to be quite high, by utilizing methods such as core-shell nanowires, quantum dot in a nanowire architecture, and selective area epitaxy (or selective area growth), which are described elsewhere.

Promising work in this field to date has been completed utilizing molecular beam epitaxy (MBE) to epitaxially deposit semiconductor layers of the nanowires. MBE is a useful technique in research and development (R&D), and is even utilized in manufacturing for certain epitaxially grown devices. However, it is in general a slower means of manufacturing. For this reason, amongst others, it is generally used in a small fraction of world-wide epitaxial production capacity. Nanowire light emitting devices are also commonly based on gallium nitride (GaN) epitaxially deposited layers. A common epitaxially deposited semiconductor crystalline structure for gallium nitride (GaN) is the Ga-polar lattice structure, where the surface of the gallium nitride (GaN) is terminated by a layer of gallium (Ga) atoms. Nanowires grown on Ga-polar crystalline structure however is characterized by a pyramidal growth at the top which deleteriously impact the performance of active light emitting structures such as quantum wells.

Accordingly, there is a continuing need for improved nanowire based light emitting devices and method of manufacturing.

### SUMMARY OF THE INVENTION

The present technology may best be understood by referring to the following description and accompanying drawings that are used to illustrate embodiments of the present technology directed toward nanowire light emitting devices and methods of manufacturing. The devices and method include growth of high-quality, high-efficiency light emitting devices utilizing epitaxy deposition. Embodiments include nanowire light emitting devices utilizing metal-organic chemical vapor deposition (MOCVD) to grow N-polar semiconductor layers, to realize high performing micro and nano light emitting devices.

In one embodiment, a method of fabricating a nanowire light emitting device structure can include depositing a n-type doped, N-polar gallium nitride (GaN) layer above a mask layer. An active region comprising a light emitting structure can be deposited above the n-type doped, N-polar gallium nitride (GaN) layer. An electron blocking layer can be deposited above the light emitting structure. A p-type doped N-polar gallium nitride (GaN) layer can be deposited above the electron blocking layer. The n-type doped, N-polar gallium nitride (GaN) layer, active region, electron blocking layer and p-type doped N-polar gallium nitride (GaN) layer can be selective area deposited in a metal-organic chemical vapor deposition (MOCVD) chamber.

In yet another embodiment, a nanowire light emitting device can include an N-polar first semiconductor region, a second semiconductor region including an active light emitting structure can be disposed on the N-polar first semiconductor region, and a third semiconductor region can be disposed on the second semiconductor region. The second semiconductor region can comprise one or more N-polar semiconductor structures. The third semiconductor region can comprise a N-polar semiconductor region. The nanowire light emitting device can further include a strain relief layer disposed between the first and second semiconductor regions. The nanowire light emitting device can also further include a hole blocking layer disposed between the first and second semiconductor regions. The nanowire light emitting device can also further include an electron blocking layer disposed between the second and third semiconductor regions.

In yet another embodiment, a method of fabricating a nanowire light emitting device can include forming an N-polar first semiconductor region of one or more nanowires. A second semiconductor region including an active light emitting structure can be formed on the N-polar first semiconductor region, and a third semiconductor region can be disposed on the second semiconductor region, of the one or more nanowires. The method can further include forming a hole blocking layer between the N-polar first semiconductor region and the second semiconductor region. The method can also further include forming a strain relief layer between the N-polar first semiconductor region and the hole blocking layer. The method can also further include forming an electron blocking layer between the second semiconductor region and the third semiconductor region. The N-polar first semiconductor region, the second semiconductor region, the third semiconductor region, and the optional hole blocking layer, optional strain relief layer and optional electron blocking layer can be formed by metal-organic chemical vapor depositing (MOCVD).

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

Embodiments of the present technology are illustrated by way of example and not by way of limitation, in the figures of the accompanying drawings and in which like reference numerals refer to similar elements and in which:

FIG. 1 shows a nanowire light emitting device, in accordance with aspects of the present technology.

FIG. 2 shows a nanowire light emitting device, in accordance with aspects of the present technology.

FIG. 3 shows a nanowire light emitting device, in accordance with aspects of the present technology.

FIG. 4 shows a method of fabricating a nanowire light emitting device, in accordance with aspects of the present technology.

FIGS. 5A-5C show semiconductor crystalline structures.

FIG. 6 shows a method of fabricating a nanowire light emitting device, in accordance with aspects of the present technology.

FIG. 7 shows a substrate and mask layer utilized for a method of fabricating a nanowire light emitting device, in accordance with aspects of the present technology.

FIG. 8 shows a nanowire light emitting device, in accordance with aspects of the present technology.

### DETAILED DESCRIPTION OF THE INVENTION

Reference will now be made in detail to the embodiments of the present technology, examples of which are illustrated in the accompanying drawings. While the present technology will be described in conjunction with these embodiments, it will be understood that they are not intended to limit the technology to these embodiments. On the contrary, the invention is intended to cover alternatives, modifications and equivalents, which may be included within the scope of the invention as defined by the appended claims. Furthermore, in the following detailed description of the present technology, numerous specific details are set forth in order to provide a thorough understanding of the present technology. However, it is understood that the present technology may be practiced without these specific details. In other instances, well-known methods, procedures, components, and circuits have not been described in detail as not to unnecessarily obscure aspects of the present technology.

Some embodiments of the present technology which follow are presented in terms of routines, modules, logic blocks, and other symbolic representations of operations on data within one or more electronic devices. The descriptions and representations are the means used by those skilled in the art to most effectively convey the substance of their work to others skilled in the art. A routine, module, logic block and/or the like, is herein, and generally, conceived to be a self-consistent sequence of processes or instructions leading to a desired result. The processes are those including physical manipulations of physical quantities. Usually, though not necessarily, these physical manipulations take the form of electric or magnetic signals capable of being stored, transferred, compared and otherwise manipulated in an electronic device. For reasons of convenience, and with reference to common usage, these signals are referred to as data, bits, values, elements, symbols, characters, terms, numbers, strings, and/or the like with reference to embodiments of the present technology.

It should be borne in mind, however, that these terms are to be interpreted as referencing physical manipulations and quantities and are merely convenient labels and are to be interpreted further in view of terms commonly used in the art. Unless specifically stated otherwise as apparent from the following discussion, it is understood that through discussions of the present technology, discussions utilizing the terms such as “receiving,” and/or the like, refer to the actions and processes of an electronic device such as an electronic computing device that manipulates and transforms data. The data is represented as physical (e.g., electronic) quantities within the electronic device's logic circuits, registers, memories and/or the like, and is transformed into other data similarly represented as physical quantities within the electronic device.

In this application, the use of the disjunctive is intended to include the conjunctive. The use of definite or indefinite articles is not intended to indicate cardinality. In particular, a reference to “the” object or “a” object is intended to denote also one of a possible plurality of such objects. The use of the terms “comprises,” “comprising,” “includes,” “including” and the like specify the presence of stated elements, but do not preclude the presence or addition of one or more other elements and or groups thereof. It is also to be understood that although the terms first, second, etc. may be used herein to describe various elements, such elements should not be limited by these terms. These terms are used herein to distinguish one element from another. For example, a first element could be termed a second element, and similarly a second element could be termed a first element, without departing from the scope of embodiments. It is also to be understood that when an element is referred to as being “coupled” to another element, it may be directly or indirectly connected to the other element, or an intervening element may be present. In contrast, when an element is referred to as being “directly connected” to another element, there are not intervening elements present. It is also to be understood that the term “and or” includes any and all combinations of one or more of the associated elements. It is also to be understood that the phraseology and terminology used herein is for the purpose of description and should not be regarded as limiting.

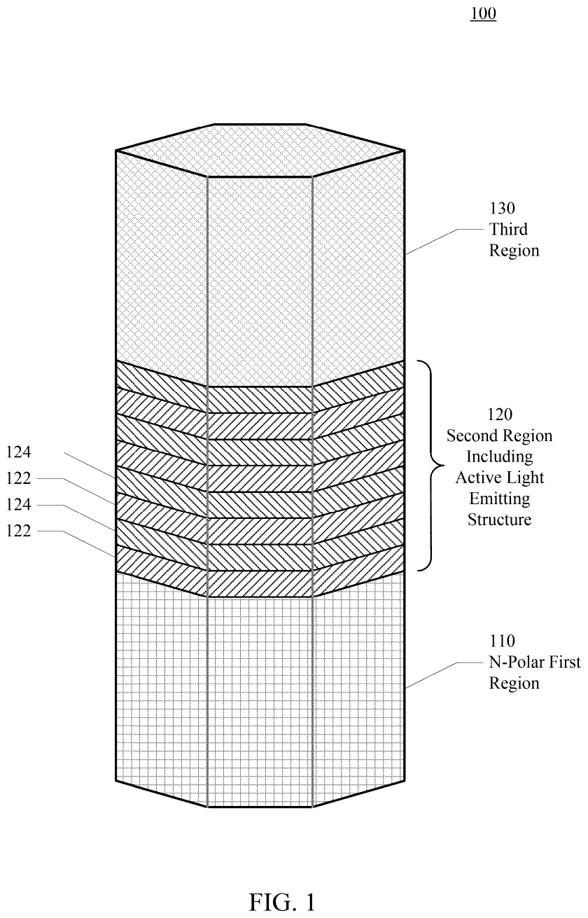

Referring now to FIG. 1, a nanowire light emitting device, in accordance with aspects of the present technology, is shown. The nanowire light emitting device 100 can include a N-polar first semiconductor region 110. The first region 110 can include a group III-V semiconductor having a N-polar crystalline structure. The N-polar crystalline structure can be a nitride terminated lattice geometry (e.g., 0001 or 0001). The N-polar crystalline structure is characterized by a substantially planar end surface, and faceted edges along the sides. The N-polar first region 110 can have a first doping type. The group V elements can be selected from a group including gallium (Ga), aluminum (Al) and indium (In), and the group III elements can be selected from a group including nitrogen (N) and phosphorous (P). In one implementation, the N-polar first semiconductor region 110 can be a N-polar gallium nitride (GaN) layer n-doped with silicon (Si). The N-polar gallium nitride (GaN) layer can be doped with silicon (Si) at a concertation of 2e19 atoms per cubic centimeters or higher. The heavily silicon (Si) doped N-polar gallium nitride (GaN) layer can be beneficial for forming an Ohmic contact and lowering the forward voltage of the nanowire light emitting device 100. The N-polar first semiconductor region 110 can have a height (e.g., length) of approximately 400 nanometer (nm) to 1 micrometer (μm), and a lateral cross-sectional width of 1 millimeter (mm) or less. In micro light emitting device implementations, the N-polar first semiconductor region 110 can have a lateral cross-sectional width of less than 100 micrometers. In nano light emitting device implementation, the N-polar first semiconductor region 110 can have a lateral cross-sectional width of less than 100 nanometers.

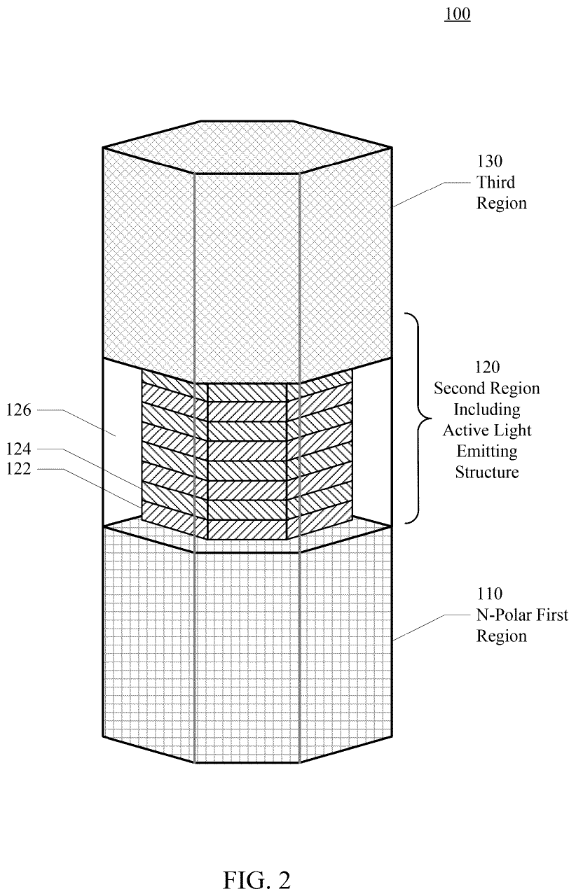

The nanowire light emitting device 100 can further include a second semiconductor region 120 including an active light emitting structure. In one implementation, the active light emitting structure can include one or more quantum wells, quantum disks, quantum dots, and or similar quantum structures. The second semiconductor region 120 can be disposed on the N-polar first semiconductor region 110. The second semiconductor region 120 disposed on the first semiconductor region 110 can have a substantially planar structure when formed on the planar surface of the N-polar first semiconductor region 110. In one implementation, the second semiconductor region 120 can also have a N-polar crystalline structure. In one implementation, the quantum structure of the active light emitting structure can comprise one or more pairs of quantum wells (QW) 122 and quantum barrier (QB) 124 layers. In one implementation, the quantum structure can include two to eight pairs of quantum wells (QW) 122 and quantum barrier (QB) 124 layers. In one implementation, the one or more quantum wells (QW) 122 can comprise indium gallium nitride (InGaN), and the one or more quantum barriers (QB) 124 can comprise aluminum gallium nitride (AlGaN). The planar active light emitting structure of second semiconductor region 120, resulting from formation on the planar surface of the N-polar first semiconductor region 110, can advantageously have less leakage current, can be better defined, and have substantially no edge or middle defects. In a quantum well or similar quantum structure implementation, the active light emitting structures can further include a quantum shell 126 disposed about the periphery of the one or more quantum wells 122 and quantum barriers 124, as illustrated in FIG. 2. The quantum shell can be spontaneously formed during deposition of the one or more pairs of quantum wells 122 and quantum barrier 124 layers. The quantum shell 126 can advantageously reduce electron hole recombination at the sidewalls of the light emitting device 100. In one implementation, the indium nitride (InN) composition is highest in the center of the indium gallium nitride (InGaN) quantum well layer, and the InN material near the edge of the quantum disc can accordingly have a higher bandgap. The average InN composition in the quantum well can depend upon the diameter of the nanowire, in such a manner that the InN composition increases at the periphery when the diameter decreases. The lateral aluminum nitride (AlN) composition can be lowest in the center of the barrier disc, while at the edges the AlN composition can be higher and again resulting in a higher bandgap around the edges of the quantum barrier disc. In one implementation, the quantum wells (QW) can be approximate 1.5 to 5 nanometer (nm) thick, and the quantum barrier (QB) layers can be approximately 2 to 8 nm thick. Generally, the parameters of the quantum well (QW) layers are designed to maximize the efficiency of light emission while the parameters of the quantum barrier layers (QB) are designed to both maximize the quantum efficiency and reduce forward voltage drop in the nanowire light emitting device 100. Another objective of the design of the active light emitting structure is filling the quantum wells (QW) with both electron and holes at about equal concentrations. Therefore, the design parameters can be selected so that holes reach the quantum wells (QW) farthest from the n-type conductive layer associated with the first semiconductor region 110, and electrons reach the quantum wells farthest from the p-type conductive layer associated with the subsequently described third semiconductor region 130 in a corresponding implementation. The quantum well (QW) structure of the active light emitting structure can be configured to generate light in the red, green and blue wavelength ranges.

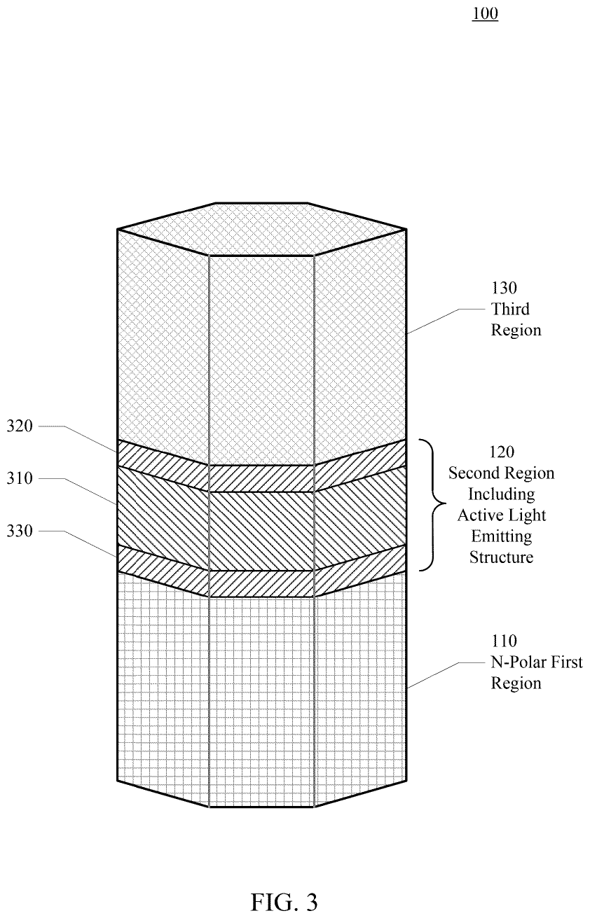

In another implementation, the active light emitting structure 130 can include a double hetero structure (DH), as illustrated in FIG. 3. The double hetero structure can include a relative thick indium gallium nitride (InGaN) layer 310 of approximately 40 to 60 nm, between two relatively thinner gallium nitride (GaN) layers 320, 330. The double hetero structure of the active light emitting structure can be configured to generate light in the red and green wavelength ranges.

The nanowire light emitting device 100 can further include a third semiconductor region 130 disposed on the second semiconductor region 120. The third semiconductor region 130 can include a group III-V semiconductor. The group V elements can be selected from a group including gallium (Ga), aluminum (Al) and indium (In), and the group III elements can be selected from a group including nitrogen (N) and phosphorous (P). The third semiconductor region 130 can have a second doping type. In one implementation, the third semiconductor region 120 can be a gallium nitride (GaN) layer p-doped with magnesium (Mg). The third semiconductor region 130 can also have a N-polar semiconductor structure. The nanowire light emitting device 100, including the first, second and third semiconductor layers, can have a substantially hexagonal, square, rectangular, rhombic, polygonal or similar faceted cross-sectional shape.

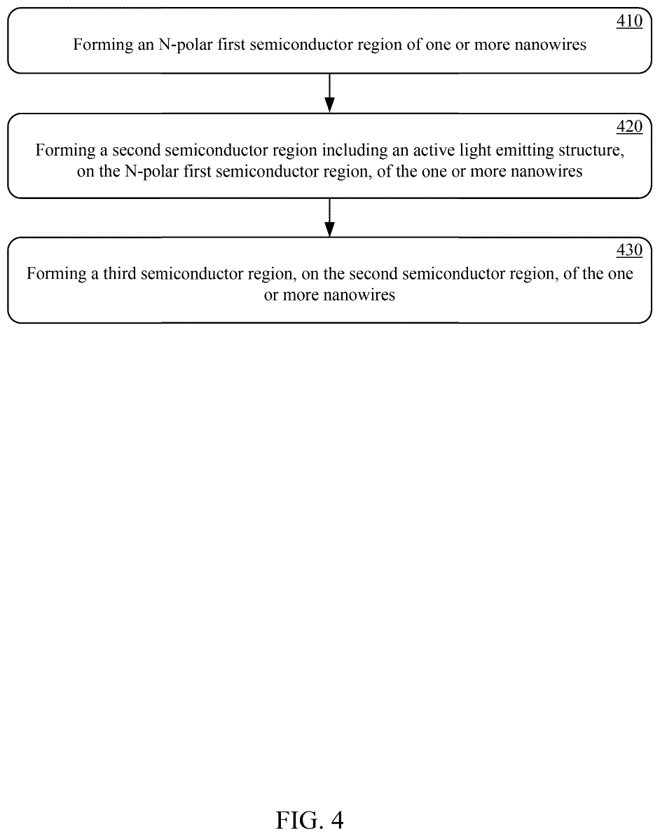

Referring now to FIG. 4, a method of fabricating a nanowire light emitting device, in accordance with aspects of the present technology, is shown. The method of fabricating can include forming a N-polar first semiconductor region, at 410. The first semiconductor region can be formed by epitaxially depositing a group III-V semiconductor having a N-polar crystalline structure. The group III-V semiconductor can be epitaxially deposited at a ratio of approximately 1:500 or less. The first semiconductor region can be doped with a first type of dopant (e.g., n-type). The group V elements can be selected from a group including gallium (Ga), aluminum (Al) and indium (In), and the group III elements can be selected from a group including nitrogen (N) and phosphorous (P). The dopant of a first type can be silicon (Si). In one implementation, the first region can be formed by metal-organic chemical vapor deposition (MOCVD) (also called metal-organic vapor phase epitaxy (MOVPE)) of a N-polar gallium nitride (GaN) layer doped with silicon (Si). The N-polar gallium nitride (GaN) layer can be doped during metal-organic chemical vapor deposition (MOCVD) with silicon (Si) at a concertation of 2e19 atoms per cubic centimeters or higher. The N-polar first semiconductor region 110 can have a height (e.g., length) of approximately 400 nanometer (nm) to 1 micrometer (μm), and a lateral cross-sectional width of 1 millimeter (mm) or less. The N-polar gallium nitride (GaN) layer can advantageously grow relatively fast as compared to other deposition process and crystalline structures, resulting in faceting of the surfaces of the growth edges of the nanowire, while having a substantially planar end surface. The heavily silicon (Si) doped N-polar gallium nitride (GaN) layer can be beneficial for forming an Ohmic contact and lowering the forward voltage of the nanowire light emitting device 100.

At 420, a second semiconductor region can be formed on the N-polar first semiconductor region. The second semiconductor region can include an active light emitting structure. In one implementation, the active light emitting structure can include one or more epitaxially deposited quantum wells, quantum disks, quantum dots, and or similar quantum structures. In one implementation, the quantum structure of the active light emitting structure can be formed by alternately depositing pairs of quantum wells (QW) and quantum barrier layers (QB) layers by metal-organic chemical vapor deposition (MOCVD). In one implementation, the quantum structure can include two to eight pairs of quantum wells (QW) and quantum barrier (QB) layers. In one implementation, the one or more quantum wells (QW) can comprise metal-organic chemical vapor deposited (MOCVD) indium gallium nitride (InGaN), and the one or more quantum barriers (QB) can comprise metal-organic chemical vapor deposited (MOCVD) aluminum gallium nitride (AlGaN). The alternating pair of indium gallium nitride (InGaN) and aluminum gallium nitride (AlGaN) layers can be metal-organic chemical vapor deposited (MOCVD) with N-polar crystalline structures. The quantum wells (QW) and quantum barrier (QB) layers can be deposited by metal-organic chemical vapor deposition (MOCVD) to further include a quantum shell disposed about the periphery of the one or more quantum wells. In one implementation, quantum shell can be a self-organized structure spontaneously formed as a result of difference in the adatom diffusion length of the indium (In) and aluminum (Al) atoms. In one implementation, the indium nitride (InN) composition is highest in the center of the indium gallium nitride (InGaN) quantum well layer, and the InN material near the edge of the quantum disc can accordingly have a higher bandgap. The average InN composition in the quantum well can depend upon the diameter of the nanowire, in such a manner that the InN composition increases at the periphery when the diameter decreases. The lateral aluminum nitride (AlN) composition can be lowest in the center of the barrier disc, while at the edges the aluminum nitride (AlN) composition can be higher and again resulting in a higher bandgap around the edges of the quantum barrier disc. In one implementation, the quantum well (QW) layers can be approximate 1.5 to 5 nanometer (nm) thick, and the quantum barrier (QB) layers can be approximately 2 to 8 nm thick.

In another implementation, the active light emitting structure can include a double hetero structure (DH). The double hetero structure can include a relative thick indium gallium nitride (InGaN) layer of approximately 40 to 60 nm between two relatively thinner gallium nitride (GaN) layers. The two gallium nitride (GaN) layers and the indium gallium nitride (InGaN) layer can be deposited by metal-organic chemical vapor deposition (MOCVD) with N-polar crystalline structures.

At 430, a third semiconductor region can be formed on the second semiconductor region. The third semiconductor region can be formed by epitaxially depositing a group III-V semiconductor. The group III-V semiconductor can be epitaxially deposited at a ratio of approximately 1:1000 or greater. The third semiconductor region can be doped with a second type of dopant (e.g., p-type). In one implementation, the third semiconductor region 110 can be a gallium nitride (GaN) layer p-doped with magnesium (Mg). In one implementation, the gallium nitride (GaN) layer doped with magnesium (Mg) can be formed by metal-organic chemical vapor deposition (MOCVD) with a N-polar crystalline structure. The N-polar gallium nitride (GaN) layer can be doped with magnesium at a concertation of 2e21 atoms per cubic centimeters. The heavily magnesium (Mg) doped N-polar gallium nitride (GaN) layer can be beneficial for forming an Ohmic contact and lowering the forward voltage of the nanowire light emitting device 100. The N-polar third semiconductor region 110 can have a height (e.g., length) of approximately 100 to 500 nm.

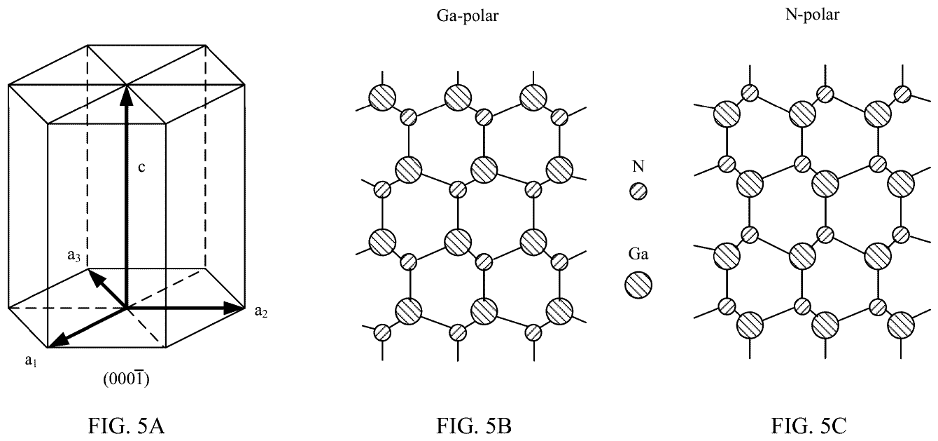

Referring now to FIGS. 5A-5C, semiconductor crystalline structures are shown. FIG. 5A illustrates a hexagonal unit cell. FIG. 5B, illustrates a Ga-polar atomic structure. In the Ga-polar atomic structure, gallium (Ga) atoms terminate the gallium nitride (GaN) semiconductor crystalline structure along the surface. Conventional metal-organic chemical vapor deposition (MOCVD) utilized to fabricate gallium nitride (GaN) based semiconductor nanowires often result is Ga-polar atomic structures. FIG. 5C illustrates a N-polar atomic structure. In the N-polar atomic structures, nitrogen (N) atoms terminate the gallium nitride (GaN), aluminum nitride (AlN), indium nitride (IN), indium gallium nitride (InGaN), aluminum gallium nitride (AlGaN) or the like semiconductor crystalline structure along the surface. To achieve N-polar atomic structures a number of factors impact the formation of the N-polar crystalline structure. Among them are: (1) the choice of the substrate and its surface condition, (2) initial nitridation of the substrate to form a N-rich surface, (3) the use of a suitable nucleation (or buffer) layer, (4) avoidance of inversion domain detects at initial stages of growth, and (5) maintenance of the N-polar growth orientation as the layer is deposited to its desired thickness.

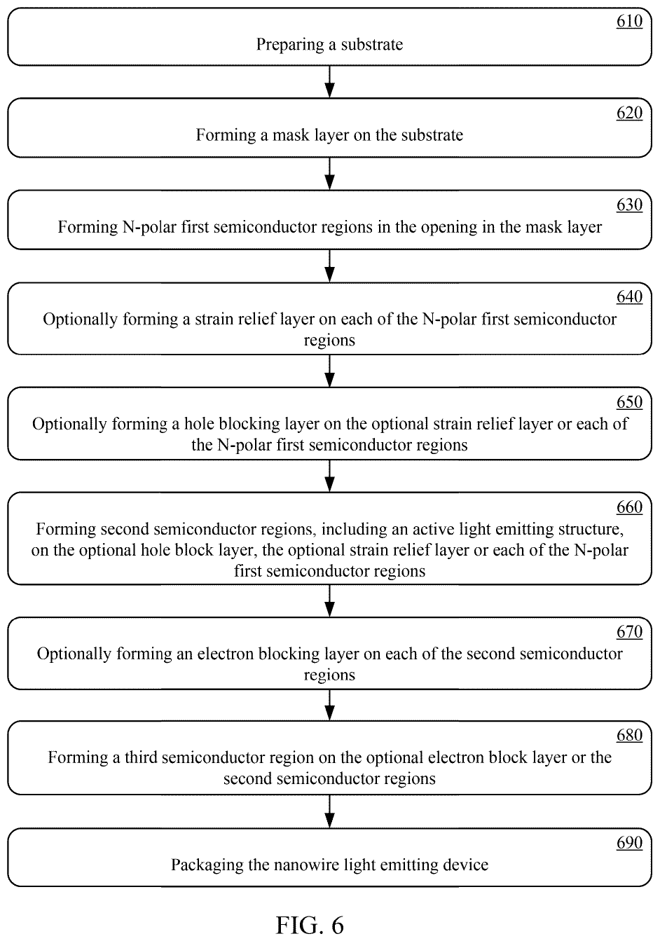

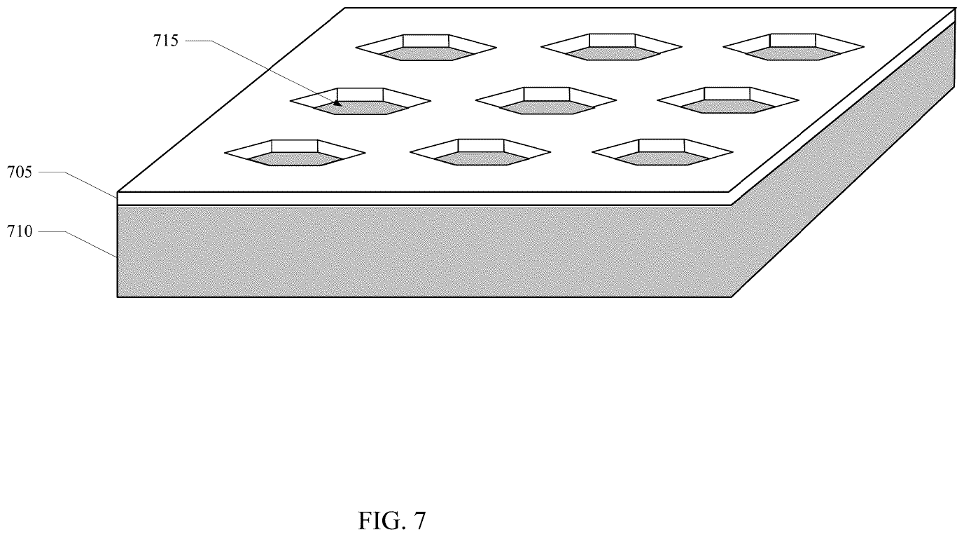

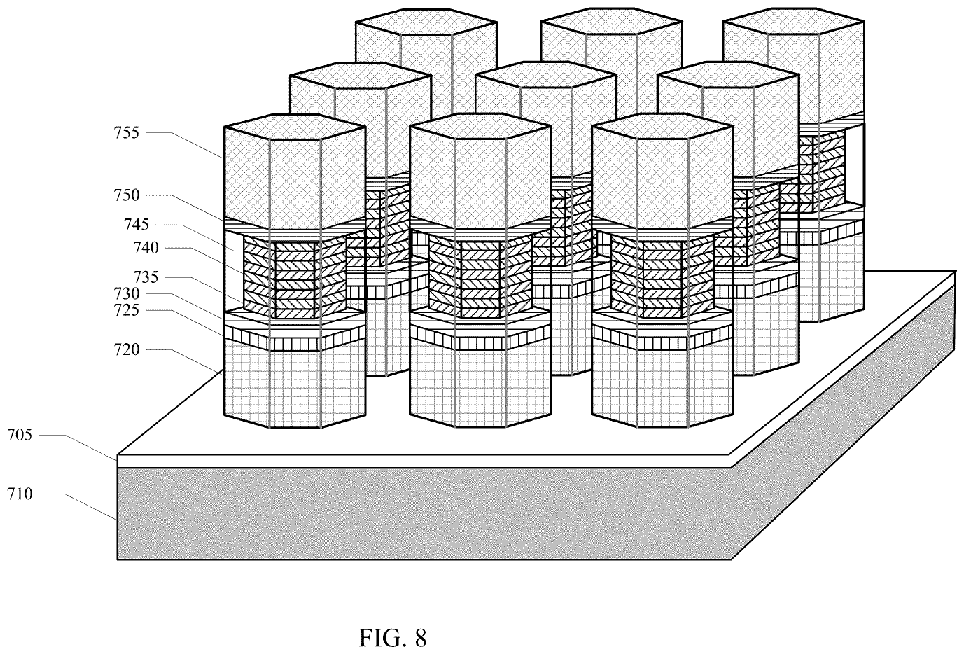

Referring now to FIG. 6, a method of fabricating a nanowire light emitting device, in accordance with aspects of the present technology, is shown. The method of fabrication will be further explained with reference to FIGS. 7 and 8, which show perspective views of fabrication of a nanowire light emitting device. Furthermore, in the following described fabrication processes, any precursor flow is usually accompanied by the flow of hydrogen (H₂) or nitrogen (N₂) and is assumed in the following descriptions even if not explicitly mentioned. Also, the amount of the gases flowed into the reaction chamber may not be explicitly provided as these amounts have a strong dependence on the size and type of the reactor chamber. Rather, the ratio of group III and group V precursors (the V-III ratio=V/III) is provided where appropriate as a more quantitatively descriptive illustration of growth conditions.

The method of fabricating can include preparing a substrate, at 610. In one implementation, the substrate can be gallium (Ga), aluminum (Al), indium (In), Silicon (Si), sapphire (Al₂O₃), silicon carbide (SiC), gallium nitride (GaN) or aluminum nitride (AlN). Sapphire, for example, is readily available in a wide range of wafer sizes, in high quantity, with high purity, and high-quality surface preparation. Sapphire substrates can have planar surface preparation (i.e., flat) or can be patterned (Patterned Sapphire Substrates, PSS) where divots of various shapes and depths are etched into the surface. These patterns are intended to prevent laterally contiguous growth at initial stages of gallium nitride (GaN) deposition leading to later reduction of the density of threading dislocations which typically form in hetero-epitaxy. In high-volume manufacturing, the preferred crystal orientation of the surface onto which the gallium (Ga), aluminum (Al) or indium (In) nitride (N) layers are to be deposited is c-plane. It has been reported that the quality of the deposited material improves when the substrate is slightly mis-oriented to the sapphire a- or m-plane up to a mis-orientation angle of about 5 degrees. A preferred range for the mis-orientation angle is between about 2 and about 4 degrees towards either plane. For silicon, the substrate surface can be oriented in the (111) crystallographic direction and it has been reported that a slight mis-orientation of the surface is also beneficial in this case for the quality of the subsequent epitaxial material.

Preparation of the substrate can include a cleaning process. In one implementation, the cleaning process can include flowing hydrogen (H₂), at temperature between about 800 and 1200 degrees Centigrade (° C.) in a metal-organic chemical vapor deposition (MOCVD) reaction chamber. In some cases, chlorine (Cl₂) can be introduced into the reactor chamber to etch the substrate surfaces prior to depositing gallium nitride (GaN) or aluminum nitride (AlN).

Preparation for a sapphire substrate can also include a nitridation step initiated by flowing a N-precursor such as ammonia (NH₃). The nitridation process is performed to promote N-polar growth. The nitridation process can be conducted for between about 1 and 30 minutes, at a temperature between about 900 and 1300° C. in a metal-organic chemical vapor deposition (MOCVD) reaction chamber. The goal of the nitridation process is to form a complete layer of nitrogen (N) atoms on top of the substrate. For example, on a sapphire substrate, nitridation forms a complete layer of nitrogen (N) atoms on top of the sapphire substrate bonded to aluminum (Al) atoms terminating the sapphire substrate surface.

Preparation of the substrate can also include depositing an N-polar nucleation or buffer layer. In one implementation, the substrate temperature can be lowered after the nitridation process, and a N-polar gallium nitride (GaN) or aluminum (AlN) nucleation layer can be deposited. The nucleation layer serves as an intermediate layer between the single-crystalline substrate and a following epitaxial single-crystalline layer of gallium nitride (GaN), aluminum nitride (AlN) or indium nitride (InN) to accommodate in-plane lattice parameter differences existing between the substrate and nitride alloy device layers. For N-polar growth the nucleation layer can be grown at a higher temperature than is customary for Ga-polar growth. The nucleation layer growth temperature can be between about 800 and about 1100° C. The deposition of the nucleation layer can be initiated by flowing gallium (Ga) or aluminum (Al) precursors such as trimethylgallium (TMGa) or trymethylaluminum (TMAl) in addition to ammonia (NH₃) into the growth chamber. The carrier gas can preferably be hydrogen (H₂), but may also be nitrogen (N₂). Hydrogen (H₂) is preferred over nitrogen (N₂) as it preferentially removes metal atoms (i.e., Ga or Al) from the growing surface allowing nitrogen atoms to terminate the deposited layers. Further, the ratio between gallium (Ga) or aluminum (Al) and nitrogen (N) precursor flow may be between about 2000 and 10000, or higher. The nucleation layer can be deposited to a thickness of about 10 to 40 nm. Alternatively, no nucleation layer may be deposited, and instead a N-polar device layer described further below may be deposited directly onto the nitridated sapphire substrate.

For silicon (Si) substrates, the deposition of an aluminum nitride (AlN) nucleation layer can be used to initiate the growth by flowing the aluminum (Al) precursor trymethylaluminum (TMAl) in addition to ammonia (NH₃) into the growth chamber. For this growth step, the substrate temperature can be between about 900 and 1300° C. Further, the use of Si substrates may include the insertion of strain relief layers above the growth initiation layer to avoid cracking of the N-polar device layer to be deposited above. Such strain relief structures may involve superlattices composed of aluminum nitride (AlN) and gallium nitride (GaN), or aluminum gallium nitride (AlGaN) and gallium nitride (GaN).

Preparation of the substrate can also include an annealing process. The annealing process can include flowing a N-precursor into the chamber while the group III metal sources are turned off. The substrate temperature may be set to the growth temperature of the N-polar device layer or to between about 900 and 1300° C.

Fabricating the nanowire light emitting device can further include forming a mask layer on the substrate, at 620. A patterned mask 705 may be deposited on a prepared substrate 710, as illustrated in FIG. 7. The patterned mask 705 can include an array of openings 715. The patterned mask layer can be deposited to achieve selective area epitaxy. Under select conditions, type III-V semiconductor device layers, of for example gallium nitride (GaN) or aluminum nitride (AlN), will grow on the exposed substrate, but not on the mask, hence the selectivity of the epitaxy process. Examples of mask materials include titanium nitride (TiN), titanium dioxide (TiO₂), silicon dioxide (SiO₂), or silicon nitride (SiN). In embodiments, a preferred mask material for selective area epitaxy is one that has a low sticking coefficient and high adatom diffusion length, and can withstand high growth temperatures and remain inert to the exposed chemistries in the reaction chamber. The mask material can be applied to the substrate surface by physical vapor deposition or chemical vapor deposition techniques. The mask layer may be relatively thin, for example on the order of 10 nm, and ideally is uniform across the substrate surface. Patterning the mask then involves a lithography and etching step to form openings with a predetermine size, and optionally predetermined shape (e.g., hexagonal, square, rectangular, rhombic, polygonal). Direct writing of the pattern (e.g., electron beam lithography, thermal scanning probe lithography, nanoimprint lithography) or an indirect method (e.g., photolithography, extreme ultraviolet lithography) may be employed. The etching of the mask material can be realized using standard microfabrication techniques, such as reactive ion etching or a lift-off process. The wafer may undergo a final cleaning process before loading into a metal-organic chemical vapor deposition (MOCVD) reaction chamber. For the selective area epitaxy of nanopillars, the patterned hole may be circular or hexagonal. In embodiments, the hole diameter may be between about 50 and 500 nm. In embodiments, the spacing between holes may be large enough to prevent unwanted coalescence of the nanopillars when accounting for a lateral growth rate. The diameter and spacing of the nanopillars may be designed to promote a photonic crystal effect and the emergence of narrow emission modes. The mask can be further stabilized by exposing the as-prepared wafers to a flow of the nitrogen precursor with a substrate temperature above the decomposition temperature of ammonia (NH₃), which may be between about 600 and 800° C. at a chamber pressure greater than about 100 millibars (mbar). Further, the process temperature may be raised higher (e.g., to 1000° C.), after initial nitridation of the mask layer has been achieved. The duration of the stabilization process may range between 1 and 10 minutes depending on chamber conditions. Alternative processes may include forming stable mask layers in ex-situ processes, eliminating the need for the mask stabilization step in the metal-organic chemical vapor deposition (MOCVD) process.

Fabricating the nanowire light emitting device can further include forming N-polar first semiconductor regions in each of the openings in the mask layer, at 630. The first region can include an epitaxially deposited group III-V semiconductor having a N-polar crystalline structure. In one implementation, a N-polar III-V semiconductor layer with a first doping type 720 can be selectively deposited in the plurality of opening in the pattern mask 705, as illustrated in FIG. 8.

In one implementation, the prepared substrate with mask layer and exposed N-polar nucleation layer may be loaded into a metal-organic chemical vapor deposition (MOCVD) reaction chamber. The system for fabricating the nanowires structures can be the same as the system used for preparing the substrate with the N-polar nucleation layer. Alternatively, it may be a separate system or a different chamber in a multi-chamber system where each chamber is optimized for performing certain growth processes. For example, the metal-organic chemical vapor deposition (MOCVD) system or chamber used for the growth of N-polar nucleation layer may only be equipped with the trimethylgallium (TMGa) source, ammonia (NH₃) and silane (SiH₄) gases, and can enable favorable conditions for the high-volume production of N-polar nucleation layers on wafers. The system or chamber employed to generate the full nanowire light emitting device structure may be optimized differently and may utilize additional precursors including trimethylaluminum (TMAl), trimethylindium (TMIn), and magnesocene (CP₂Mg).

In one implementation, forming the N-polar first semiconductor region can include raising the substrate temperature to about 1100° C. During this phase of the process, either hydrogen (H₂), nitrogen (N₂), ammonia (NH₃), or a combination of these gases can be flowing into the reaction chamber to stabilize the exposed N-polar nucleation surfaces during the temperature ramp. In one implementation, growth of N-polar gallium nitride (GaN) can be initiated by flowing the gallium (Ga) precursor trimethylgallium (TMGa) into the chamber. It is preferred that the growth temperature stays constant during the growth of the main N-polar, n-type GaN layer as the deposition of a low-temperature nucleation layer is not required. Yet, the growth temperature may vary between about 1000 and 1300° C. to achieve desired properties. The N-polar first semiconductor region can be formed to a thickness of about 400 to 1000 nm. An objective at this stage of the process is to ensure growth of N-polar gallium nitride (GaN) as hexagonal pillars over the openings in the mask layer. Source material arriving on top of the masked portions of the wafer is expected to desorb so that no gallium nitride (GaN) growth is initiated on these sections of the wafer. A further aspect of the growth at this stage is the bending of threading dislocations possibly penetrating from the substrate towards nano-pillar surfaces. The III-N N-polar nano-pillars described in the present disclosure are expected to be free of structural defects. Growth conditions are selected to favor vertical or axial growth in c-crystallographic direction of N-polar material and limit growth laterally on the pillar sidewalls to avoid coalescence of the nano-pillars at this early stage of the process. Hence, the reactor pressure may be at about 100 mbar or lower, and the ratio of V/III elements may be about 500 or lower. Generally, reaction chamber pressure and V/III ratio are maintained at lower values for growth of N-polar gallium nitride (GaN) nano-pillars than would be the case for growth of standard planar light emitting device structures.

In one implementation, a pulsed growth of the N-polar first semiconductor region can be provided, wherein group III and group V precursors are not continuously provided to the reaction chamber. The pulsed growth method can enable precise control of the shape of the N-polar III-N nano-pillars using selective area growth by metal-organic chemical vapor deposition (MOCVD). In one implementation, pulsed growth of N-polar gallium nitride (GaN) may proceed with injection of trimethylgallium (TMGa) precursor into the growth chamber for time periods of one or more seconds while ammonia (NH₃) is not flowing into the chamber. Similarly, ammonia (NH₃) may be injected into the reaction chamber for time periods of one or more seconds while trimethylgallium (TMGa) flow is turned off. The injection periods of either precursor may be separated by time periods of one or more seconds where no precursors flow into the chamber. Typically, a carrier gas such as hydrogen (H₂) is flowing continuously. An example process may include a 1 second pulse of trimethylgallium (TMGa) injection, a 1 second pause with no injection, a 1 second pulse of ammonia (NH₃) injection again followed by a 1 s long pause. Alternatively, the sequence may begin with ammonia (NH₃) injection, or the time periods of precursor injection may have a different length than the pauses. Other embodiments may keep one of the precursors flowing in a continuous fashion while the other precursor is interrupted at periodic intervals. Injection and pause time periods may extend beyond 1 second but are expected not to be longer than 5 seconds. The established sequence repeats until the desired layer thickness is achieved. Alternatively, time periods may be adapted during the growth of the full nanowire light emitting device structure to achieve desired growth behavior.

Another consideration for selecting growth conditions is impurity incorporation. Conditions are selected that limit incorporation of impurities such as carbon (C) and oxygen (O). Carbon is omnipresent in the reaction chamber as it is a constituent of the metalorganic precursors (e.g., TMGa). Oxygen may be a contaminant in any of the precursors or gases injected into the growth chamber or may enter through an unintended leak in plumbing system or the chamber. It is the aim of the present invention to keep carbon and oxygen concentrations below about 1017 atoms per cubic centimeters in most layers of the nanowire light emitting devices.

The first semiconductor region can be doped with a first doping type (e.g., n-doping). In one implementation, silicon (Si) doping can be enabled by the metered flow of silane (SiH₄) together with the gallium (Ga) precursor leading to Si incorporation in the range between 2e18 and 1e19 atoms per cubic centimeters. In the case of pulsed growth, flow of the dopant precursors may accompany the flow of trimethylgallium (TMGa), or may be injected separately into the growth chamber. The doping concentration may be uniform through the thickness of the N-polar n-doped gallium nitride (GaN) layer or may exhibit a step-like doping profile with Si concentration increasing in the latter part of the n-type conductive gallium nitride (GaN) layer. However, while higher silicon (Si) concentrations may be desirable, silicon (Si) concentrations greater than 1e19 atoms per cubic centimeters typically lead to rough surface morphology that is undesirable for the growth of nanowire light emitting device structures. In general, growth conditions for silicon (Si) doped (e.g., n-type conductive) N-polar GaN layer is selected to maximize conductivity (i.e., the mathematical product of carrier concentration and electron mobility).

Fabricating the nanowire light emitting device can optionally further include forming a strain relief layer on each of the N-polar first semiconductor regions, at 640. The strain relief layer 725 can be selectively deposited on each of the plurality of N-polar first semiconductor regions 720, as further illustrated in FIG. 8. The strain relief layer can include an epitaxially group III-V semiconductor having a N-polar crystalline structure with a lattice constant between that of the first semiconductor region and one or more subsequently formed semiconductor layers. The strain relief structure can be considered beneficial for the growth of the active region deposited above the strain relaxation structure. More specifically, in one implementation it may promote the incorporation of indium (In) atoms leading to higher indium nitride (InN) content in the light emitting region. For example, the formation of indium gallium nitride (InGaN) quantum discs with high and uniform indium nitride (InN) composition along the growth direction of the light emitting region can reduce the compositional pulling effect often observed in multiple quantum well active region stacks. The strain relaxation structure may comprise a single N-polar indium gallium nitride (InGaN) layer of modest indium nitride (InN) composition (e.g., between 5 and 15% InN). Alternatively, the structure may include a superlattice composed of alternating thin N-polar indium gallium nitride (InGaN) and N-polar gallium nitride (GaN) layers. Here, the indium nitride (InN) composition of the indium gallium nitride (InGaN) layers may range between 10 and 30%. In other embodiments the indium nitride (InN) compositions may reach up to 20% in a single indium gallium nitride (InGaN) layer, and up to 40% in indium gallium nitride (InGaN) layers as part of a superlattice strain relaxation structure. In one implementation, the strain relief layers can be deposited by metal-organic chemical vapor deposition (MOCVD). To enable the growth of indium gallium nitride (InGaN) layers, indium (In) atoms can be provided into the growth chamber by the precursor trimethylindium (TMIn) using hydrogen (H₂) or nitrogen (N₂) as carrier gas. The total thickness of the strain relaxation structure may be between about 100 and 500 nm. In the case of a superlattice, 10 pairs of InGaN/GaN layers may be included, but more or fewer pairs using thinner or thicker layers, respectively, can also be considered. The incorporation of indium (In) into the crystal lattice is promoted by lowering the growth temperature. The growth temperature for the strain relaxation structure may be selected from the range between about 800 to 1000° C. In the case of the superlattice, the substrate temperature may be adjusted higher for growth of the gallium nitride (GaN) layers and lower for the growth of the indium gallium nitride (InGaN) layers. The strain relaxation structure is preferably doped with silicon (Si), but may be partially doped with silicon (Si), or remain undoped. While the incorporation of a strain relaxation structure may be optional it is expected to be advantageous for green and red light emitting nanowire structures. Here, the active region of the light emitting device structure contains indium gallium nitride (InGaN) layers with high indium nitride (InN) composition (e.g., up to 50% InN) requiring an expanded in-plane lattice constant. The above-described embodiments of strain relaxation structures have the potential to provide such function and enable green and red light emitting nanowire devices.

Fabricating the nanowire light emitting device can optionally further include forming a hole blocking layer on the optional strain relief layer or each of the N-polar first semiconductor regions, at 650. The hole block layer can include an epitaxially group III-V semiconductor having a N-polar crystalline structure. The hole blocking layer may be positioned between the optional strain relaxation structure and the light emitting active region. In the case where there is no strain relaxation structure, the hole blocking layer may be positioned directly above the n-type conductive N-polar first semiconductor region (e.g., N-polar Si-doped GaN layer). In one implementation, the optional hole blocking layer 730 can be selective deposited on the strain relief layer 725, as further illustrated in FIG. 8. The hole blocking layer can prevent positive carriers (e.g., holes) from overflowing the active light emitting region. In one implementation, the hole blocking layer can include N-polar aluminum gallium nitride (AlGaN) and positioned directly below the active region. In one implementation, the N-polar aluminum gallium nitride (AlGaN) hole blocking layer can be deposited by metal-organic chemical vapor deposition (MOCVD). The hole blocking layer can be doped with silicon (Si), but may remain undoped. The aluminum nitride (AlN) composition of this layer may be between about 10 to 30%. If doped with silicon (Si), the silicon (Si) concentration may be about 1e19 atoms per cubic centimeters. The thickness of the hole blocking layer can be between about 10 to 50 nm. The incorporation of aluminum (Al) can be achieved by flowing the precursor trimethylindium (TMIn) into the chamber. The carrier gas can be nitrogen (N₂), but alternatively may be hydrogen (H₂). The growth temperature can be between about 1000 to 1300° C. Reactor chamber pressure for growth of aluminum gallium nitride (AlGaN) and the V/III ratio are generally lower than for growth of gallium nitride (GaN), and are preferably about 500 mbar or less, respectively.

Fabricating the nanowire light emitting device can further include forming second semiconductor regions including an active light emitting structure, at 660. The second semiconductor regions can be formed on the optional hole block layer, the optional strain relief layer or each of the N-polar first semiconductor regions. In one implementation, the active light emitting structure can include one or more pairs of quantum wells (QW) 735 and quantum barriers (QB) 740 selectively deposited on the optional hole blocking layer 735, as further illustrated in FIG. 8. In one implementation, the active light emitting structure can include six or fewer pairs of quantum wells (QW) and quantum barriers (QB) to form a multi-quantum well active region (MQW). In one implementation, the quantum wells (QW) may be epitaxially deposited indium gallium nitride (InGaN) layers, and the quantum barrier (QB) may be epitaxially deposited aluminum gallium nitride (AlGaN) layers. In one implementation, the indium nitride (InN) composition in the indium gallium nitride quantum wells can be high enough to achieve green (about 530 nm) or red (about 620 nm) light emission. The quantum wells may have lateral non-uniformity in the indium nitride (InN) composition, wherein the composition is highest in the center of quantum discs, while the composition is lower at the edges (i.e., the InN material near the edge of the quantum discs have a higher bandgap). The average indium nitride (InN) composition in a quantum well can depend on the diameter of the nano-pillar in such a manner that the indium nitride (InN) composition increases when the lateral diameter decreases while growth conditions remain unchanged. Nano-pillars with different diameters incorporate different amount of indium nitride (InN), wherein nano-pillars with smaller/larger diameters will emit at longer/shorter wavelengths even when positioned on the same wafer and generated in the same growth run. In one implementation, the aluminum gallium nitride (AlGaN) quantum barrier layers may have lateral non-uniformity in the aluminum nitride (AlN) composition, wherein the composition is lowest in the center of barrier discs, while at the edges the aluminum nitride (AlN) composition is higher. This arrangement results in higher bandgap material to be positioned around the edges of the quantum barrier discs.

The one or more pairs of quantum wells (QW) and quantum barriers (QB) can be formed by the metal-organic chemical vapor deposition (MOCVD). In one implementation, quantum well layers can be grown to a thickness of between about 1.5 to 5 nm by flowing trimethylindium (TMIn), triethylgallium (TEGa), and ammonia (NH₃) into the reactor chamber. The growth temperature may be between about 700 and 1000° C. depending on the desired emission wavelength. The V/III ratio may range between about 500 and 10000, and the reactor pressure may be between about 100 and 500 mbar. An objective for the growth of well layers may be to allow indium (In) atoms to distribute laterally across the diameter of the quantum well disc in the manner described above. For example, the growth temperature may be selected high enough to force desorption of indium (In) atoms preferentially from the pillar edges. Pulsed growth may be employed to limit the nitrogen (N) supply to support the removal of indium (In) atoms from the pillar edges. Similarly, trimethylindium (TMIn) and trimethylgallium (TMGa) may be supplied independently to achieve a higher indium nitride (InN) composition in the center of the indium gallium nitride (InGaN) quantum well (QW) discs. Independent of the growth conditions, the average indium nitride (InN) composition of the indium gallium nitride (InGaN) quantum well (QW) discs can depend on pillar diameter where a smaller nano-pillar will allow higher indium nitride (InN) composition due to strain relaxation.

In one implementation, disposition of the quantum barrier (QB) layers uses higher growth temperature than the quantum well (QW) layers due to low surface mobility of aluminum (Al). However, initial growth of the aluminum gallium nitride (AlGaN) quantum barrier (QB) layer directly on top of a quantum well (QW) layer may be conducted at temperatures close to the growth temperature of the quantum well (QW) layer to protect the indium gallium nitride (InGaN) quantum well (QW) and be raised while the quantum barrier (QB) layer is deposited. Quantum barrier (QB) layers can be grown to a thickness of between about 2 to 8 nm by flowing trimethylindium (TMIn), triethylgallium (TEGa) and ammonia (NH₃) into the reaction chamber. The growth temperature may vary between about 900 to 1200° C. The V/III ratio may range between about 100 and 1000, and the reactor pressure may range between about 50 and 100 mbar. Alternatively, the chamber pressure may be maintained at the value selected for growth of the indium gallium nitride (InGaN) quantum wells (QW) (e.g., about 100 mbar or higher). The aluminum nitride (AlN) composition of the quantum barrier (QB) layers is expected to exhibit a lateral distribution profile as described above. The accumulation of aluminum (Al) atoms around the outer portions of the quantum barrier (BQ) disc may be enabled by selecting the growth temperature high enough so that aluminum (Al) atoms can have sufficient mobility to incorporate preferentially at the outer portions of the quantum barrier (QB) discs. Such behavior may further be supported by using pulsed growth where trimethylindium (TMIn) is provided without ammonia (NH₃) into the chamber for a period of time.

In one implementation, the formation of the desired distribution of indium (In) atoms, with indium (In) atoms preferentially incorporating in the center of the quantum well (QW) discs, and the desired distribution of aluminum (Al) atoms, with aluminum (Al) atoms preferentially incorporating near the outer portions of the quantum barrier (QB) discs, may be aided by an annealing step following the growth of a quantum well (QW) or the growth of a quantum barrier (QB) layer. Here, the substrate temperature may be maintained at the growth temperature of the respective layer while only ammonia (NH₃) (and nitrogen (N₂)) is flowing into the growth chamber and held for a time period of between about 30 seconds to 5 minutes. Alternatively, the temperature may be raised higher after well growth or held constant after barrier growth and then lowered to grow the next well layer. In one implementation, the average indium nitride (InN) composition of the well layers may range between about 10 and 50% depending on desired emission wavelength. The average aluminum nitride (AlN) composition of the barrier layer may be between about 10 and 30%. In one implementation, carrier gas for growth of both well and barrier layers is preferably nitrogen (N₂), as hydrogen (H₂) is understood to limit the incorporation of indium nitride (InN). The precursor for gallium Ga can be switched to triethylgallium (TEGa) vs. trimethylgallium (TMGa) for growing the light emitting region as triethylgallium (TEGa) is understood to reduce the incorporation of carbon (C) into the growing layer. The quantum wells (QW) 735 and quantum barrier (QB) layers 740 can be deposited by metal-organic chemical vapor deposition (MOCVD) to further include a quantum shell 745 disposed about the periphery of the one or more quantum wells, as further illustrated in FIG. 8. In one implementation, quantum shell 745 can be a self-organized structure spontaneously formed as a result of difference in the adatom diffusion length of the indium (In) and aluminum (Al) atoms.

The metal-organic chemical vapor deposition (MOCVD) growth of the second semiconductor region in a hydrogen rich environment can result in a second semiconductor region having an appreciable amount of hydrogen impurities. For example, metal-organic chemical vapor deposition (MOCVD) of the one or more pairs of quantum wells (QW) and quantum barriers (QB) in the presence of a hydrogen (H₂) carrier gas or hydrogen rich precursors such as ammonia (NH₃) can result in quantum wells (QW) and quantum barriers (QB) with an appreciable concentration of hydrogen impurities. In one implementation, the concentration of hydrogen impurities can be greater then???.

Generally, the design of the quantum well (QW) layers is optimized to maximize quantum efficiency of light emission while design of the quantum barrier (QB) layers in addition to maximizing the quantum efficiency also considers reducing forward voltage of the light emitting device during operation. Hence, quantum barrier (QB) layers may be doped or partially doped with silicon (Si) and/or contain a shaped compositional profile along the growth direction of the nanopillar light emitting device. Another objective for the active region of the present light emitting devices is filling of the quantum disc layers with both electron and holes at about equal concentrations. Therefore, it is desired that electrons reach the quantum disc farthest from the n-type conductive layer and holes reach the quantum disc farthest from the p-type conductive layer. Again, such design will maximize the light emission quantum efficiency.

Two different embodiments are envisioned for the structure of the multi quantum well (MQW) active region layer stack. A first embodiment begins with the growth of a indium gallium nitride (InGaN) quantum well (QW) layer directly after an aluminum gallium nitride (AlGaN) hole blocking layer that is grown, or directly after the strain relaxation structure in cases where the hole blocking layer is absent. The quantum well (QW) layer may be grown directly on the N-polar, n-type GaN first semiconductor layer in cases where there is neither a hole blocking layer nor a strain relaxation structure. A second embodiment begins the growth of the multi quantum well (MQW) active region with an aluminum gallium nitride (AlGaN) quantum barrier (QB) layer. The growth of the quantum barrier (QB) layer may be initiated directly on top of the hole blocking layer, the strain relaxation structure, or the N-polar, n-type GaN first semiconductor layer depending on presence of the optional strain relaxation structure or optional hole blocking layer. The multi quantum well (MQW) active region may be terminated with a quantum barrier (QB) to properly protect the last quantum well (QW) layer from subsequent growth.

In other implementations, the light emitting active region may assume an entirely different structure, especially for green and red light emitting nanowires. Instead of depositing alternating layers of quantum wells and quantum barriers, a thicker indium gallium nitride (InGaN) layer may be provided. The thickness of the single indium gallium nitride (InGaN) layer may range between about 20 and 70 nm, and its growth temperature may range between about 800 and 1000° C. A preferred thickness may be about 40 nm for green emission, and about 60 nm for red emission. The indium gallium nitride (InGaN) layer may be sandwiched between two gallium nitride (GaN) layers with thicknesses less than the thickness of the indium gallium nitride (InGaN) light emitting layer. Such composites are labelled a “double hetero structure” (DH) active region. The DH active region may be embedded between hole and electron blocking layers in similar fashion as described above for the MQW active region.

For either type of active region (MQW or DH), growth conditions provide vertical or axial growth with negligible accumulation of material in the lateral direction to avoid coalescence of the individual nano-pillars. Similar methods as described for growth of the N-polar, n-type GaN first semiconductor layer leading to preferential growth in the vertical direction are expected to apply for the growth of the active region. In one implementation, an optional annealing step may follow completion of the active region growth. Here the substrate temperature may be maintained at the level of the growth temperature of the final aluminum gallium nitride (AlGaN) quantum barrier (WB) layer for a duration of about 1 to 5 minutes while at least ammonia (NH₃) is flowing into the reaction chamber. Alternatively, the temperature may be raised higher than the growth temperature of the final barrier layer.

Fabricating the nanowire light emitting device can optionally further include forming an electron blocking layer on each of the second semiconductor regions, at 670. In one implementation, the electron block layer 750 can be selectively deposited one each of the second semiconductor regions 735-745, as further illustrated in FIG. 8. The electron block layer can include an epitaxially group III-V semiconductor having a N-polar crystalline structure. In one implementation, the electron blocking layer may be composed of N-polar aluminum gallium nitride (AlGaN) doped with magnesium (Mg). In one implementation, the N-polar aluminum gallium nitride (AlGaN) doped with magnesium (Mg) electron blocking layer can be deposited by metal-organic chemical vapor deposition (MOCVD). The electron blocking layer can be grown by flowing trimethylaluminum (TMAl) and trimethylgallium (TMGa) into the reaction chamber using nitrogen (N₂) as a carrier gas. The substrate temperature may be maintained between about 900 and 1200° C., and the V/III ratio may be between about 100 and 1000. The reactor pressure may be between about 50 and 150 mbar. Magnesium (Mg) doping can be enabled by flowing magnesocene (CP₂Mg) into the chamber. The target magnesium (Mg) doping can be between about 5e19 and 5e20 Mg atoms per cubic centimeters. The target thickness of the electron blocking layer can be between about 10 and 50 nm.

Fabricating the nanowire light emitting device can further include forming a third semiconductor region on the optional electron block layer or the second semiconductor regions, at 680. In one implementation, the third semiconductor region 755 can be selectively deposited on each of the electron blocking layers 750, as further illustrated in FIG. 8. The third semiconductor region can be formed by epitaxially depositing a group III-V semiconductor. In one implementation, a N-polar magnesium (Mg) doped gallium nitride (GaN) layer can be deposited by metal-organic chemical vapor deposition (MOCVD) on the optional electron blocking layer, or on the second semiconductor region including the active light emitting structure. The thickness of the N-polar magnesium (Mg) doped gallium nitride (GaN) layer can be between about 100 to 300 nm. The growth temperature for this layer can be lower than the growth temperature of the electron blocking layer, at between about 900 to 1100° C. The V/III ratio can be selected to be larger than about 1000, and the reactor pressure may be about 100 mbar or higher. It is desirable for this final layer to have a smooth morphology, and the growth conditions can be selected to achieve this objective. In another implementation, the growth conditions of the p-doped, N-polar gallium nitride (GaN) layer are selected to strongly promote growth in lateral growth directions to achieve coalescence of the nano-pillars forming a uniform and cohesive layer connecting all pillars at the top of the nanowire light emitting device layer stack. Such coalescence can be achieved by increasing the V/III ratio and the reactor pressure. For example, the V/III ratio may be selected to be about 20000 and the reactor pressure may be selected to be about 300 mbar or higher. Alternatively, the V/III ratio may be about 10000 or lower and the reactor pressure may be lower than 300 mbar. Further, it has been reported that the presence of magnesium (Mg) promotes growth in the crystallographic direction perpendicular to the c-axis. To achieve full coalescence the N-polar, p-type conductive gallium nitride (GaN) layer may have to be grown thicker than in the above-described case of non-coalesced nano-pillars. An exemplary thickness for the coalesced p-doped gallium nitride (GaN) layer can be between about 200 and 500 nm. In yet another implementation, the nano-pillar light emitting device layer stack may contain a final top-layer with higher magnesium (Mg) concentration than is present in the p-type conductive layer. The magnesium (Mg) doping may be raised to between about 5e20 and 2e21 atoms per cubic centimeters. Such a heavily doped (e.g., p++) layer may have a thickness of about 50 nm. In the case where the p++ layer is present, the p-type conductive gallium nitride (GaN) layer may be grown thinner so that the entire thickness of all magnesium (Mg) doped layer is limited to about 250 nm in the non-coalesced and about 350 nm in the coalesced case. The formation of the N-polar magnesium (Mg) doped gallium nitride (GaN) layer can end by turning off the flow of group III precursors into the chamber and ramping the substrate temperature to a value of about 600° C. while ammonia (NH₃) is provided to stabilize the grown material.

The metal-organic chemical vapor deposition (MOCVD) growth of the third semiconductor region in a hydrogen rich environment can result in a third semiconductor region having an appreciable amount of hydrogen impurities. For example, metal-organic chemical vapor deposition (MOCVD) in the presence of a hydrogen (H₂) carrier gas or hydrogen rich precursors such as ammonia (NH₃) can result in a third semiconductor region with an appreciable concentration of hydrogen impurities. In one implementation, the third semiconductor can have a hydrogen impurity concentration of greater than???. The hydrogen impurity concentration can identify the formation of the third semiconductor region, and if applicable, also the second semiconductor region has been formed by metal-organic chemical vapor deposition (MOCVD). An optional thermal cycle can be included to drive the hydrogen impurities out of the third semiconductor region, and if applicable, also the second semiconductor region. In one implementation, the formation of the N-polar magnesium (Mg) doped gallium nitride (GaN) layer can end with activation of p-type conductivity in the Mg-doped epitaxial layers. Due to the presence of hydrogen (H₂) in the growth chamber, magnesium (Mg) and hydrogen (H) form complexes in the growing crystal that are electrically inactive. Activation and, therefore, p-type conductivity, can be achieved by exposing the as-grown wafers to a thermal treatment conducted at about 600° C. in a hydrogen (H) free atmosphere. Hence, the present invention can include the process of p-conductivity activation in the MOCVD growth chamber (i.e., in situ Mg activation). To achieve this objective, the substrate temperature can be maintained in a range between about 550 and 700° C. for a duration of about 15 minutes while only nitrogen (N₂) is flowed into the reactor chamber. Care is taken to purge the chamber with nitrogen (N₂) to remove any hydrogen (H₂) (or ammonia (NH₃)) before the activation can take place. After completion of this final optional process step, the reactor temperature is further lowered, and the nanowire light emitting device wafers can be removed from the chamber.

Fabricating the nanowire light emitting device can further include packaging the nanowire light emitting device, at 690. The packaging processes can include forming contacts. The electrodes can be formed for uncoalesced nanowire implementations and for uncoalesced nanowire implementations. In one implementation, the fabrication of the nanowire light emitting devices can include atomic layer deposition (ALD) of aluminum oxide (Al₂O₃) to fill the air gap of the nanowire array for coalesced nanowires embodiments. The fill process can be terminated when no air gaps can be physically observed by scanning electron microscope (SEM). The top of the third semiconductor regions (e.g., the p-doped GaN) of the individual nanowire can then be revealed by a fluorine-based reactive ion etching (RIE) process. Plasma-enhanced chemical vapor deposition of 200-500 nm silicon oxide (SiO₂) is performed as an insulation layer, followed by lithography and reactive ion etching (RIE) to open current injection window in the silicon oxide (SiO₂) layer for each nanowire light emitting device structure. Metal stacks including 1-5 nm of nickel (Ni), 1-5 nm of gold (Au) and 100-300 nm of indium tin oxide (ITO) can be used as a p-metal contact. The indium tin oxide (ITO) can be deposited via a sputtering process to ensure excellent coverage on the sidewall of the silicon oxide (SiO₂) insulation layer. On the other end of the nanowire, a chlorine-based reactive ion etch (RIE) process can be used to etch down into the first semiconductor region (e.g., the n-doped GaN). The contact of 10-30 nm to tin (Ti) and 50-150 nm of gold (Au) can be deposited for n-metal contact. After formation of the contacts, the device can further be annealed in nitrogen (N₂) ambient at 550° C. for 1 minute.

In another implementation, for coalesced nanowires, the nanowire light emitting device structure can be annealed to activate p-type conductivity in a hydrogen (H) free ambient at a temperature between about 550 to 700° C. for about 15 minutes. After the annealing step, mesas can be defined following industry standard processes. For example, a lithography step can define mesa areas ranging from 1 to 5 μm on the sides or from 1 to 20 μm depending on application of the nanowire light emitting devices. Each light emitting device can include a multitude of nanopillars. Mesas can be etched with a similar process to that described above for uncoalesced nanowire light emitting devices until the N-polar, n-type conductive gallium nitride (GaN) layer is exposed. Metal layers can be deposited to achieve Ohmic contacts to the n-type conductive and p-type conductive gallium nitride (GaN) layers of the nanowires. The n-type contact metallization can be deposited onto the N-polar, n-type conductive gallium nitride (GaN) layer ideally at a depth where the silicon (Si) doping concentration is greater than 1e19 atoms per cubic centimeters. The metal stack may be similar to the metals described above for uncoalesced nanowire light emitting devices, but other metals are feasible as long as an Ohmic contact to N-polar, n-type conductive gallium nitride (GaN) can be achieved. For the p-side, in a first implementation, a transparent p-metallization stack can be deposited. In this configuration, light is extracted from the nanowire light emitting device through the transparent metallization. Metal layers may consist of materials described above for uncoalesced structure with similar layer thicknesses. In a second implementation, a reflective metal layer can be deposited. Here, light generated in the active region of the nanowire light emitting device is reflected into the structure and extracted through the sapphire substrate. Such a configuration can be referred to as “flip-chip light emitting devices.” A typical metal used can be silver (Ag), which provides the function of forming an Ohmic contact with heavily magnesium (Mg) doped, p-type gallium nitride (GaN) and is highly reflective to visible light. The silver (Ag) layer thickness may range from about 100 to 300 nm and may be covered by another metal layer or by indium tin oxide (ITO).

Packaging can further include dicing the non-coalesced or coalesced nanowire light emitting devices into individual light emitting device chips or chips containing groups of light emitting devices by thinning the sapphire substrate by mechanical polishing or etching to a thickness of about 100 nm. It is envisioned that all fabrication steps use standard high volume processing tools suitable for mass manufacturing of nanowire LEDs.

Nanowire light emitting devices, in accordance with aspects of the present technology, can advantageously yield very high efficiency devices at very small sizes. For example, external quantum efficiency (EQE) greater than 1% and even greater than 10% can be achieved for red, green, and blue LEDs. Metal-organic chemical vapor deposition (MOCVD) of the nanowire devices described herein advantageously provides for higher production throughput and or lower production cost, as compared to forming such nanowire device utilizing molecular beam epitaxy (MBE).

The following examples pertain to specific technology embodiments and point out specific features, elements, or steps that may be used or otherwise combined in achieving such embodiments.

Example 1 includes a method of fabricating a nanowire light emitting device structure in a metal-organic chemical vapor deposition (MOCVD) chamber, the method comprising: depositing a n-type doped, N-polar gallium nitride (GaN) layer above a mask layer; depositing an active region comprising a light emitting structure above the n-type doped, N-polar gallium nitride (GaN) layer; depositing an electron blocking layer above the light emitting structure; and depositing a p-type doped N-polar gallium nitride (GaN) layer above the electron blocking layer.

Example 2 includes the method of Example 1, wherein the mask layer is a stable mask layer formed in an ex-situ process.

Example 3 includes the method of Example 1, further comprising stabilizing the mask layer prior to depositing the n-type doped, N-polar gallium nitride (GaN) layer.

Example 4 includes the method of Example 3, wherein said stabilizing the mask layer comprises nitridation of the mask layer.

Example 5 includes the method of Example 4, wherein the substrate temperature is in a range between 600° C. and 800° C., and wherein the metal-organic chemical vapor deposition (MOCVD) chamber pressure is at least 100 mbar.

Example 6 includes the method of Example 5, further comprising increasing the substrate temperature above 800° C. after initial nitridation of the mask layer is achieved.

Example 7 includes the method of Example 1, wherein said depositing the n-type doped, N-polar gallium nitride (GaN) layer comprises: initiating growth of the N-polar gallium nitride (GaN) by flowing a gallium (Ga) precursor into the MOCVD chamber, wherein growth conditions are selected to favor vertical or axial growth in the c-crystallographic direction of the N-polar material and limit growth laterally on the sidewalls;

and enabling silicon (Si) doping of the gallium nitride (GaN)) by flowing a silicon (Si) precursor with the gallium (Ga) precursor.

Example 8 includes the method of Example 7, further comprising maintaining a constant temperature during the growth.

Example 9 includes the method of Example 7, wherein a pressure inside the metal-organic chemical vapor deposition (MOCVD) chamber is not greater than 100 mbar and a ratio of gallium (Ga) and nitrogen (N) precursors is not greater than 500.

Example 10 includes the method of Example 9, wherein each of the group III and the group V precursors are not continuously provided to the metal-organic chemical vapor deposition (MOCVD) chamber.

Example 11 includes the method of Example 7, further comprising maintaining carbon (C) and oxygen (O) concentrations in the metal-organic chemical vapor deposition (MOCVD) chamber below about 1017 atoms per cubic centimeters.

Example 12 includes the method of Example 7, wherein the silicon (Si) has a doping concentration in the range between 2e18 cm-3 and 1e19 atoms per cubic centimeters.

Example 13 includes the method of Example 12, wherein the silicon (Si) doping concentration is uniform through the thickness of the silicon (Si) doped N-polar gallium nitride (GaN)) layer.

Example 14 includes the method of Example 12, wherein the silicon (Si) doping concentration exhibits a step-like doping profile with the Si doping concentration increasing in the latter part of the silicon (Si) doped N-polar gallium nitride (GaN) layer.

Example 15 includes the method of Example 1, wherein the light emitting structure comprises multiple pairs of quantum well (QW) and quantum barrier (QB) layers forming a multi-quantum well active region (MQW).

Example 16 includes the method of Example 15, wherein each quantum well (QW) layer comprises indium gallium nitride (InGaN), wherein the indium nitride (InN) composition is high enough to achieve green or red emission, and wherein the indium nitride (InN) composition is highest in the center of each quantum disc.

Example 17 includes the method of Example 15, wherein each quantum barrier (QB) layer comprises aluminum gallium nitride (AlGaN), and wherein the aluminum nitride (AlN) composition is lowest in the center of each barrier disc.

Example 18 includes the method of Example 15, further comprising performing an annealing step following the growth of a quantum well (QW) or the growth of a quantum barrier (QB) layer.

Example 19 includes the method of Example 18, wherein substrate temperature is maintained at a growth temperature of the respective quantum well (QW) or quantum barrier (QB) layer for a time period between about 30 seconds and about 5 minutes.

Example 20 includes the method of Example 18, wherein substrate temperature is increased after growth of a quantum well (QW).

Example 21 includes the method of Example 18, wherein substrate temperature is held constant after growth of a quantum barrier (QB) layer and then lowered to grow the next quantum well (QW).

Example 22 includes the method of Example 15, wherein the quantum barrier (QB) layers are doped or partially doped with silicon (Si).

Example 23 includes the method of Example 15, wherein the quantum barrier (QB) layers contain a shaped compositional profile along the growth direction of the nanowire light emitting device structure.

Example 24 includes the method of Example 15, further comprising: when an aluminum gallium nitride (AlGaN) hole blocking layer is grown, growing an indium gallium nitride (InGaN) quantum well (QW) layer directly after the aluminum gallium nitride (AlGaN) hole blocking layer is grown; when an aluminum gallium nitride (AlGaN) hole blocking layer is not grown, growing an indium gallium nitride InGaN quantum well (QW) layer directly after a strain relaxation structure is grown; and when neither an aluminum gallium nitride (AlGaN) hole blocking layer nor a strain relaxation structure is grown, growing an indium gallium nitride InGaN quantum well (QW) layer directly on the n-type doped, N-polar gallium nitride (GaN) layer.

Example 25 includes the method of Example 15, further comprising growing the multi-quantum well active region (MQW) active region with a quantum barrier (QB) layer, wherein the quantum barrier (QB) layer is directly on a hole blocking layer when the hole blocking layer is grown, or on a strain relaxation structure when the strain relaxation structure is present, and otherwise directly on the n-type doped, N-polar gallium nitride (GaN) layer.

Example 26 includes the method of Example 1, wherein the electron blocking layer comprises N-polar aluminum gallium nitride (AlGaN) doped with magnesium (Mg), and wherein said depositing the electron blocking layer comprises flowing trymethylaluminum (TMAl) and trimethylgallium (TMGa) into the metal-organic chemical vapor deposition (MOCVD) chamber using nitrogen (N₂) as a carrier gas.

Example 27 includes the method of Example 26, wherein substrate temperature is maintained in a range between about 900° C. and 1200° C., wherein a ratio of group III and group V precursors is in a range between about 100 and 1000, and wherein metal-organic chemical vapor deposition (MOCVD) chamber pressure is in a range between about 50 mbar and 150 mbar.

Example 28 includes the method of Example 26, further comprising enabling magnesium (Mg) doping by flowing magnesocene (CP₂Mg) into the metal-organic chemical vapor deposition (MOCVD) chamber, wherein magnesium (Mg) doping is in a range between about 5e19 and 5e20 atoms per cubic centimeters.

Example 29 includes the method of Example 1, wherein a growth temperature of the p-type doped N-polar gallium nitride (GaN) layer is in a range from about 900° C. to 1100° C., wherein a ratio of group III and group V precursors is greater than about 1000, and wherein a metal-organic chemical vapor deposition (MOCVD) chamber pressure is not less than 100 mbar.

Example 30 includes the method of Example 1, further comprising, after said depositing the p-type doped N-polar gallium nitride (GaN) layer: turning off flow of group III precursors into the p-type doped N-polar gallium nitride (GaN) chamber; and ramping substrate temperature to a value of about 600° C. while providing ammonia (NH₃).

Example 31 includes the method of Example 1, further comprising, after depositing the n-type doped, N-polar gallium nitride (GaN) layer: depositing a strain relief structure.

Example 32 includes the method of Example 31, wherein the strain relief structure comprises a single N-polar indium gallium nitride (InGaN) layer comprising between about 5% and 15% indium nitride (InN).

Example 33 includes the method of Example 31, wherein the strain relief structure comprises a superlattice comprising alternating N-polar indium gallium nitride (InGaN) and N-polar gallium nitride (GaN) layers.

Example 34 includes the method of Example 1, further comprising, after said depositing the p-type doped N-polar gallium nitride (GaN) layer: depositing a hole blocking layer comprising N-polar aluminum gallium nitride (AlGaN).

Example 35 includes the method of Example 34, wherein the hole blocking layer is doped with silicon (Si).

Example 36 includes the method of Example 34, further comprising incorporating the aluminum (Al) by flowing precursor trymethylaluminum (TMAl) into the metal-organic chemical vapor deposition (MOCVD) chamber with a carrier gas that is selected from the group consisting of: nitrogen (N₂) and hydrogen (H₂).

Example 37 includes the method of Example 34, wherein growth temperature for depositing the hole blocking layer is in a range from about 1000° C. to 1300° C., wherein metal-organic chemical vapor deposition (MOCVD) chamber pressure for depositing the hole blocking layer is not greater than about 100 mbar, and wherein a ratio of group III and group V precursors for depositing the hole blocking layer is not greater than about 500.

Example 38 includes the method of Example 1, wherein the nanowire light emitting device structure comprises uncoalesced nanowires, and wherein the method further comprises: depositing aluminum oxide (Al₂O₃) to fill gaps of a nanowire light emitting device array, wherein said depositing the aluminum oxide (Al₂O₃) is terminated when no gaps are observed; revealing the top p-type doped N-polar gallium nitride (GaN) of each nanowire light emitting device by a fluorine-based reactive ion etching (RIE) process; performing plasma-enhanced chemical vapor deposition of silicon oxide (SiO₂) as an insulation layer, followed by lithography and reactive ion etching (RIE) etching to open a current injection window for each nanowire light emitting device; depositing indium tin oxide (ITO) via a sputtering process to cover a sidewall of the silicon oxide (SiO₂) insulation layer; performing a chlorine-based reactive ion etching (RIE) process to etch down into the n-type doped, N-polar gallium nitride (GaN); and annealing the structure in a nitrogen (N₂) ambient at about 550° C. for about 1 minute.

Example 39 includes the method of Example 1, wherein the nanowire light emitting device structure comprises coalesced nanowires, and wherein the method further comprises selecting growth conditions of the p-type doped N-polar gallium nitride (GaN) layer promote growth in lateral growth directions to achieve coalescence of the p-type doped N-polar gallium nitride (GaN).

Example 40 includes the method of Example 39, wherein said selecting the growth conditions comprises selecting a ratio of group III and group V precursors to be about 20,000 and the metal-organic chemical vapor deposition (MOCVD) chamber pressure to be about 300 mbar or higher.

Example 41 includes the method of Example 39, wherein said selecting the growth conditions comprises selecting a ratio of group III and group V precursors to be not greater than about 10,000 and the metal-organic chemical vapor deposition (MOCVD) chamber pressure to be lower than about 300 mbar.

Example 42 includes a nanowire light emitting device comprising: an N-polar first semiconductor region; a second semiconductor region disposed on the N-polar first semiconductor region, the second semiconductor region include an active light emitting structures; and a third semiconductor region disposed on the second semiconductor region, wherein the third semiconductor region is characterized by the presence of hydrogen impurities.

Example 43 includes the nanowire light emitting device of Example 42, wherein the second semiconductor region comprises an N-polar second semiconductor region.

Example 44 includes the nanowire light emitting device of Example 42 wherein the active light emitting structure includes one or more sets of a quantum well layer and a quantum barrier layer.

Example 45 includes the nanowire light emitting device of Example 42, wherein the active light emitting structure includes a double hetero structure.

Example 46 includes the nanowire light emitting device of Example 42, wherein the third semiconductor region comprises a N-polar third semiconductor region.

Example 47 includes the nanowire light emitting device of Example 42, wherein; the N-polar first semiconductor region comprises a N-polar group III-V semiconductor doped with a first type of dopant; the active light emitting structure includes one or more pairs of N-polar group III-V semiconductor quantum wells (QW) and N-polar group III-V semiconductor quantum barriers (QB) disposed between the N-polar group III-V semiconductor quantum wells (QW); and the third semiconductor region comprises a N-polar group III-V semiconductor doped with a second type of dopant.

Example 48 includes the nanowire light emitting device of Example 42, wherein: the N-polar first semiconductor region is disposed on a single-crystalline sapphire (Al₂O₃) substrate and the N-polar first semiconductor region comprises a N-polar gallium nitride (GaN) layer doped with silicon (Si); the active light emitting structure includes one or more pairs of N-polar indium gallium nitride (InGaN) quantum wells (QW) and N-polar aluminum gallium nitride (AlGaN) quantum barriers (QB) disposed between the N-polar indium gallium nitride (InGaN) quantum wells; and the third semiconductor region comprises a N-polar gallium nitride (GaN) layer doped with magnesium (Mg).

Example 49 includes the nanowire light emitting device of Example 48, wherein the active light emitting structure further includes a N-polar aluminum gallium nitride (AlGaN) shell disposed about a periphery of the one or more pairs of N-polar indium gallium nitride (InGaN) quantum wells (QW) and N-polar aluminum gallium nitride (AlGaN) quantum barriers (QB).

Example 50 includes the nanowire light emitting device of Example 42, wherein: the N-polar first semiconductor region is disposed on a single-crystalline sapphire (Al₂O₃) substrate and the N-polar first semiconductor region comprises a N-polar gallium nitride (GaN) layer doped with silicon (Si); the active light emitting structure includes one or more pairs of N-polar indium gallium nitride (InGaN) quantum wells (QW) and N-polar gallium nitride (GaN) quantum barriers (QB) disposed between the N-polar indium gallium nitride (InGaN) quantum wells; and the third semiconductor region comprises a N-polar gallium nitride (GaN) layer doped with magnesium (Mg).

Example 51 includes a method of fabricating a nanowire light emitting device comprising: forming an N-polar first semiconductor region of one or more nanowires; forming a second semiconductor region including an active light emitting structure, on the N-polar first semiconductor region, of the one or more nanowires; and forming a third semiconductor region, on the second semiconductor region, of the one or more nanowires.

Example 52 includes the method according to Example 51, wherein: forming the N-polar first semiconductor region comprises epitaxially depositing a N-polar group III-V semiconductor doped with a first type of dopant on a substrate; forming the second semiconductor region including the active light emitting structure includes epitaxially depositing one or more pairs of N-polar group III-V semiconductor quantum wells (QW) and N-polar group III-V semiconductor quantum barriers (QB) on the N-polar group III-V semiconductor doped with a first type of dopant, wherein the N-polar group III-V semiconductor quantum barriers (QB) are disposed between the N-polar group III-V semiconductor quantum wells (QW); and forming the third semiconductor region comprises epitaxially depositing a N-polar group III-V semiconductor doped with a second type of dopant on the one or more pairs of N-polar group III-V semiconductor quantum wells (QW) and N-polar group III-V semiconductor quantum barriers (QB).

Example 53 includes the method according to Example 51, further comprising: forming a hole blocking layer between the N-polar first semiconductor region and the second semiconductor region, wherein the hole blocking layer comprises a N-polar aluminum gallium nitride (AlGaN) layer.

Example 54 includes the method according to Example 53, further comprising: forming a strain relief layer between the N-polar first semiconductor region and the hole blocking layer, wherein the strain relief layer comprises a N-polar indium gallium nitride (InGaN) layer.

Example 55 includes the method according to Example 53, further comprising: forming an electron blocking layer between the second semiconductor region and the third semiconductor region, wherein the electron blocking layer comprises a N-polar aluminum gallium nitride (AlGaN) doped with magnesium (Mg).

Example 56 includes the method according to Example 51, further comprising: preparing a substrate selected from a group consisting of gallium (Ga), aluminum (Al), indium (In), Silicon (Si), sapphire (Al₂O₃), silicon carbide (SiC), gallium nitride (GaN) or aluminum nitride (AlN), wherein preparing the substrate includes forming a layer of nitrogen (N) atoms on the substrate; and forming a mask layer on the prepared substrate, wherein the mask layer includes a pattern of sub-micron openings.

Example 57 includes the method according to Example 56, wherein: forming the N-polar first semiconductor region comprises metal-organic chemical vapor depositing (MOCVD) a N-polar gallium nitride (GaN) layer doped with silicon (Si) on the nitrogen layer of atoms on the substrate exposed by the openings in the mask layer; forming the second semiconductor region including the active light emitting structure comprises metal-organic chemical vapor depositing (MOCVD) one or more pairs of N-polar indium gallium nitride (InGaN) quantum wells (QW) and N-polar aluminum gallium nitride (AlGaN) quantum barriers (QB) disposed on the N-polar gallium nitride (GaN) layer doped with silicon (Si); and forming the third semiconductor region comprises metal-organic chemical vapor depositing (MOCVD) a N-polar gallium nitride (GaN) layer doped with magnesium (Mg) on the one or more pairs of N-polar indium gallium nitride (InGaN) quantum wells (QW) and N-polar aluminum gallium nitride (AlGaN) quantum barriers (QB).

Example 58 includes the method according to Example 57, wherein metal-organic chemical vapor depositing (MOCVD) one or more pairs of N-polar indium gallium nitride (InGaN) quantum wells (QW) and N-polar aluminum gallium nitride (AlGaN) quantum barriers (QB) further forms a shell about a periphery of the one or more pairs of N-polar indium gallium nitride (InGaN) quantum wells (QW) and N-polar aluminum gallium nitride (AlGaN) quantum barriers (QB), wherein the shell comprises N-polar aluminum gallium nitride (AlGaN).

Example 59 includes the method according to Example 56, wherein: forming the N-polar first semiconductor region comprises metal-organic chemical vapor depositing (MOCVD) a N-polar gallium nitride (GaN) layer doped with silicon (Si) on the nitrogen layer of atoms on the substrate exposed by the openings in the mask layer; forming the second semiconductor region including the active light emitting structure comprises metal-organic chemical vapor depositing (MOCVD) one or more pairs of N-polar indium gallium nitride (InGaN) quantum wells (QW) and N-polar gallium nitride (GaN) quantum barriers (QB) disposed on the N-polar gallium nitride (GaN) layer doped with silicon (Si); and forming the third semiconductor region comprises metal-organic chemical vapor depositing (MOCVD) a N-polar gallium nitride (GaN) layer doped with magnesium (Mg) on the one or more pairs of N-polar indium gallium nitride (InGaN) quantum wells (QW) and N-polar gallium nitride (GaN) quantum barriers (QB).

The foregoing descriptions of specific embodiments of the present technology have been presented for purposes of illustration and description. They are not intended to be exhaustive or to limit the present technology to the precise forms disclosed, and obviously many modifications and variations are possible in light of the above teaching. The embodiments were chosen and described in order to best explain the principles of the present technology and its practical application, to thereby enable others skilled in the art to best utilize the present technology and various embodiments with various modifications as are suited to the particular use contemplated. It is intended that the scope of the invention be defined by the claims appended hereto and their equivalents.

What is claimed is:

1. A method of fabricating a nanowire light emitting device structure in a metal-organic chemical vapor deposition (MOCVD) chamber, the method comprising:
depositing a n-type doped, N-polar gallium nitride (GaN) layer above a mask layer;
depositing an active region comprising a light emitting structure above the n-type doped, N-polar gallium nitride (GaN) layer;
depositing an electron blocking layer above the light emitting structure; and
depositing a p-type doped N-polar gallium nitride (GaN) layer above the electron blocking layer.

2. The method of claim 1, further comprising stabilizing the mask layer in an ex-situ process prior to depositing the n-type doped, N-polar gallium nitride (GaN) layer.

3. The method of claim 1, wherein said depositing the n-type doped, N-polar gallium nitride (GaN) layer comprises:
initiating growth of the N-polar gallium nitride (GaN) by flowing a gallium (Ga) precursor into the MOCVD chamber, wherein growth conditions are selected to favor vertical or axial growth in the c-crystallographic direction of the N-polar material and limit growth laterally on the sidewalls; and
enabling silicon (Si) doping of the gallium nitride (GaN)) by flowing a silicon (Si) precursor with the gallium (Ga) precursor.

4. The method of claim 1, wherein the light emitting structure comprises multiple pairs of quantum well (QW) and quantum barrier (QB) layers forming a multi-quantum well active region (MQW).

5. The method of claim 1, wherein the electron blocking layer comprises N-polar aluminum gallium nitride (AlGaN) doped with magnesium (Mg), and wherein said depositing the electron blocking layer comprises flowing trymethylaluminum (TMAl) and trimethylgallium (TMGa) into the metal-organic chemical vapor deposition (MOCVD) chamber using nitrogen (N2) as a carrier gas.

6. The method of claim 1, wherein a growth temperature of the p-type doped N-polar gallium nitride (GaN) layer is in a range from about 900° C. to 1100° C., wherein a ratio of group III and group V precursors is greater than about 1000, and wherein a metal-organic chemical vapor deposition (MOCVD) chamber pressure is not less than 100 mbar.

7. The method of claim 1, further comprising, after said depositing the p-type doped N-polar gallium nitride (GaN) layer:
turning off flow of group III precursors into the p-type doped N-polar gallium nitride (GaN) chamber; and
ramping substrate temperature to a value of about 600° C. while providing ammonia (NH₃).

8. The method of claim 1, further comprising, after depositing the n-type doped, N-polar gallium nitride (GaN) layer: depositing a strain relief structure.

9. The method of claim 1, further comprising, after said depositing the p-type doped N-polar gallium nitride (GaN) layer: depositing a hole blocking layer comprising N-polar aluminum gallium nitride (AlGaN).

10. The method of claim 1, wherein the nanowire light emitting device structure comprises uncoalesced nanowires, and wherein the method further comprises:
depositing aluminum oxide (Al₂O₃) to fill gaps of a nanowire light emitting device array, wherein said depositing the aluminum oxide (Al₂O₃) is terminated when no gaps are observed;
revealing the top p-type doped N-polar gallium nitride (GaN) of each nanowire light emitting device by a fluorine-based reactive ion etching (RIE) process;
performing plasma-enhanced chemical vapor deposition of silicon oxide (SiO₂) as an insulation layer, followed by lithography and reactive ion etching (RIE) etching to open a current injection window for each nanowire light emitting device;
depositing indium tin oxide (ITO) via a sputtering process to cover a sidewall of the silicon oxide (SiO₂) insulation layer;
performing a chlorine-based reactive ion etching (RIE) process to etch down into the n-type doped, N-polar gallium nitride (GaN); and
annealing the structure in a nitrogen (N₂) ambient at about 550° C. for about 1 minute.

11. The method of claim 1, wherein the nanowire light emitting device structure comprises coalesced nanowires, and wherein the method further comprises selecting growth conditions of the p-type doped N-polar gallium nitride (GaN) layer to promote growth in lateral growth directions to achieve coalescence of the p-type doped N-polar gallium nitride (GaN).

12. A nanowire light emitting device comprising:
an N-polar first semiconductor region;
a second semiconductor region disposed on the N-polar first semiconductor region, the second semiconductor region include an active light emitting structures; and
a third semiconductor region disposed on the second semiconductor region, wherein the third semiconductor region is characterized by the presence of hydrogen impurities.

13. The nanowire light emitting device of claim 12, wherein the second semiconductor region comprises an N-polar second semiconductor region.

14. The nanowire light emitting device of claim 12, wherein the active light emitting structure includes one or more sets of a quantum well layer and a quantum barrier layer.

15. The nanowire light emitting device of claim 12, wherein the active light emitting structure includes a double hetero structure.

16. The nanowire light emitting device of claim 12, wherein:
the N-polar first semiconductor region is disposed on a single-crystalline sapphire (Al₂O₃) substrate and the N-polar first semiconductor region comprises a N-polar gallium nitride (GaN) layer doped with silicon (Si);
the active light emitting structure includes one or more pairs of N-polar indium gallium nitride (InGaN) quantum wells (QW) and N-polar aluminum gallium nitride (AlGaN) quantum barriers (QB) disposed between the N-polar indium gallium nitride (InGaN) quantum wells; and
the third semiconductor region comprises a N-polar gallium nitride (GaN) layer doped with magnesium (Mg).

17. The nanowire light emitting device of claim 12, wherein:
the N-polar first semiconductor region is disposed on a single-crystalline sapphire (Al₂O₃) substrate and the N-polar first semiconductor region comprises a N-polar gallium nitride (GaN) layer doped with silicon (Si);
the active light emitting structure includes one or more pairs of N-polar indium gallium nitride (InGaN) quantum wells (QW) and N-polar gallium nitride (GaN) quantum barriers (QB) disposed between the N-polar indium gallium nitride (InGaN) quantum wells; and
the third semiconductor region comprises a N-polar gallium nitride (GaN) layer doped with magnesium (Mg).

18. A method of fabricating a nanowire light emitting device comprising:
forming an N-polar first semiconductor region of one or more nanowires;
forming a second semiconductor region including an active light emitting structure, on the N-polar first semiconductor region, of the one or more nanowires; and
forming a third semiconductor region, on the second semiconductor region, of the one or more nanowires.

19. The method according to claim 18, wherein:
forming the N-polar first semiconductor region comprises epitaxially depositing a N-polar group III-V semiconductor doped with a first type of dopant on a substrate;
forming the second semiconductor region including the active light emitting structure includes epitaxially depositing one or more pairs of N-polar group III-V semiconductor quantum wells (QW) and N-polar group III-V semiconductor quantum barriers (QB) on the N-polar group III-V semiconductor doped with a first type of dopant, wherein the N-polar group III-V semiconductor quantum barriers (QB) are disposed between the N-polar group III-V semiconductor quantum wells (QW); and
forming the third semiconductor region comprises epitaxially depositing a N-polar group III-V semiconductor doped with a second type of dopant on the one or more pairs of N-polar group III-V semiconductor quantum wells (QW) and N-polar group III-V semiconductor quantum barriers (QB).

20. The method according to claim 18, further comprising:
forming a hole blocking layer between the N-polar first semiconductor region and the second semiconductor region, wherein the hole blocking layer comprises a N-polar aluminum gallium nitride (AlGaN) layer.

21. The method according to claim 18, further comprising:
preparing a substrate selected from a group consisting of gallium (Ga), aluminum (Al), indium (In), Silicon (Si), sapphire (Al₂O₃), silicon carbide (SiC), gallium nitride (GaN) or aluminum nitride (AlN), wherein preparing the substrate includes forming a layer of nitrogen (N) atoms on the substrate; and
forming a mask layer on the prepared substrate, wherein the mask layer includes a pattern of sub-micron openings.
